(19) United States
(12) Patent Application Publication
(10) Pub. No.: US 2026/0332187 A1
(43) Pub. Date: Oct. 22, 2026

(54) DEVICE AND METHOD FOR WIRELESS COMMUNICATION

(71) Applicant: Samsung Electronics Co., Ltd., Suwon-si (KR)

(72) Inventors: Eunhye PARK, Suwon-si (KR); Sukjin JUNG, Suwon-si (KR)

(21) Appl. No.: 19/578,325

(22) Filed: Mar. 25, 2026

(30) Foreign Application Priority Data
Apr. 22, 2025 (KR) 10-2025-0052312

(51) Int. Cl. H04B 1/717; H03H 17/02; H03M 1/66; H04B 1/7183

(52) U.S. Cl. CPC H04B 1/7172; H03H 17/02; H03M 1/66; H04B 1/7183

(57) ABSTRACT

A method of generating a transmission signal for wireless communication includes generating a pulse signal from input samples defining repeated patterns, generating a digital input signal by dithering the pulse signal, generating an analog output signal by performing digital to analog conversion with respect to the digital input signal, and generating the transmission signal from the analog output signal.

### CROSS-REFERENCE TO RELATED APPLICATIONS

This application claims the benefit of Korean Patent Application No. 10-2025-0052312, filed on Apr.22, 2025, in the Korean Intellectual Property Office, the disclosure of which is incorporated herein by reference in its entirety.

### BACKGROUND

### 1. Field

Example embodiments relate to communication, and more specifically, to a device and a method for wireless communication.

### 2. Description of the Related Art

In a wireless communication field, signal processing with high speed and high precision is essentially required, and an analog to digital converter (ADC) and a digital to analog converter (DAC) are being widely utilized. The performance of a DAC which converts a digital signal into an analog signal at a transmitting end affects the quality of an overall system, and a quantization error of a DAC acts as one of main factors causing distortion of an output signal. A DAC converts an inputted digital value into an analog voltage at a predetermined number of bits, and a quantization error, which is a difference between an input value and an output value, occurs by digital to analog conversion.

A quantization error reduces a signal-to-noise ratio (SNR) in a high-frequency and high-speed communication system, and deteriorates the quality of a modulation signal, thereby afflicting a negative effect on the performance of an overall system. Accordingly, various correction technologies are being researched in order to minimize a quantization error.

### SUMMARY

An aspect provides a method and a device which reduce a quantization error which occurs in digital to analog conversion in wireless communication.

According to an aspect, there is provided a method of generating a transmission signal for wireless communication comprising generating a pulse signal from input samples defining repeated patterns, generating a digital input signal by dithering the pulse signal, generating an analog output signal by performing digital to analog conversion with respect to the digital input signal, and generating the transmission signal from the analog output signal.

According to an aspect, there is provided a method of generating a transmission signal for wireless communication, comprising generating a first pulse signal and a second pulse signal respectively to correspond to identical patterns from input samples, generating a first digital input signal and a second digital input signal respectively by dithering the first pulse signal and the second pulse signal, generating a first analog output signal and a second analog output signal respectively by performing digital to analog conversion with respect to the first digital input signal and the second digital input signal, and generating the transmission signal from the first analog output signal and the second analog output signal, wherein the second digital input signal is different from the first digital input signal.

According to an aspect, there is provided a device for generating a transmission signal for wireless communication comprising a pulse shape filter configured to generate a pulse signal from input samples defining repeated patterns, a dithering processor configured to generate a digital input signal by dithering the pulse signal, a digital to analog converter configured to generate an analog output signal from the digital input signal, and a transceiver configured to generate the transmission signal from the analog output signal.

### BRIEF DESCRIPTION OF THE FIGURES

These and/or other aspects, features, and advantages of the invention will become apparent and more readily appreciated from the following description of example embodiments, taken in conjunction with the accompanying drawings of which:

FIG. 1 illustrates a wireless communication system including a wireless communication apparatus according to an example embodiment of the present disclosure;

FIG. 2A is a block diagram illustrating a processing circuitry of a wireless communication apparatus according to an example embodiment of the present disclosure;

FIG. 2B is a block diagram illustrating a dithering processor according to an example embodiment of the present disclosure;

FIG. 3 displays a quantization value and a pulse signal value according to an example embodiment of the present disclosure;

FIG. 4 is a structure chart illustrating transmission data according to an example embodiment of the present disclosure;

FIG. 5 illustrates transmission data according to an example embodiment of the present disclosure;

FIGS. 6A and 6B are graphs illustrating a repeated pattern and a pulse signal according to an example embodiment of the present disclosure;

FIG. 7 is a graph illustrating a normalized pulse signal according to an example embodiment of the present disclosure;

FIGS. 8A and 8B are graphs illustrating a quantization result of digital to analog conversion according to an example embodiment of the present disclosure;

FIG. 9 is a graph illustrating a quantization error in a wireless communication apparatus according to an example embodiment of the present disclosure;

FIG. 10 is a graph illustrating a dithering result according to an example embodiment of the present disclosure;

FIG. 11 illustrates a flowchart of a method for reducing a quantization error according to an example embodiment of the present disclosure;

FIG. 12 illustrates a flowchart of a method for reducing a quantization error according to an example embodiment of the present disclosure; and

FIG. 13 is a drawing illustrating examples of a device for wireless communication according to an example embodiment of the present disclosure.

### DETAILED DESCRIPTION

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

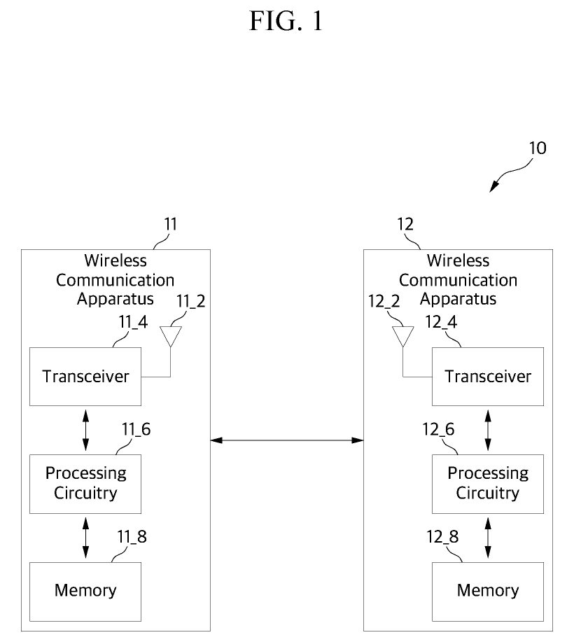

FIG. 1 is a drawing illustrating a wireless communication system 10 according to an example embodiment of the present disclosure. Specifically, FIG. 1 illustrates the wireless communication system 10 including hardware and software for the transmission and reception of a fixed repeated signal. For instance, the wireless communication system 10 may be an ultra wideband (UWB) system.

Specific example embodiments of the present disclosure are described mainly with respect to a wireless communication system transmitting a fixed repeated signal, for example, in accordance with the Institute of Electrical and Electronics Engineers (IEEE) 802.15.4 standard. However, the present disclosure is applicable to other communication systems having similar technical backgrounds and channel types, for example, cellular communication systems such as long term evolution (LTE), LTE-advanced (LTE-A), new radio (NR), wireless broadband (WiBro) and global system for mobile communication (GSM), or short-range communication systems such as Bluetooth and near field communication (NFC), without departing from the scope of the present disclosure.

UWB communication is a wireless communication method which uses a very broad bandwidth (e.g., 500 MHz or greater), and may transmit and receive data based on a pulse of a short time interval. In some example embodiments, due to the ability to perform high-resolution time synchronism and distance measurement, UWB communication is applicable to various fields such as an indoor positioning system, a short-distance high-speed data communication, a radar system and the like.

In UWB communication, a transmitted frame has a predetermined structure, and the frame may include a fixed signal for reception synchronization and channel detection. For example, a first wireless communication apparatus 11 may transmit a signal including a repeated synchronization header (SHR), and a second wireless communication apparatus 12 may detect a reception point in time based on a repeated signal, and may stably demodulate data received afterwards. The repeated SHR signal has a pre-arranged time interval and pulse pattern, and may be utilized for time synchronism and recognizing a frame boundary in the second wireless communication apparatus 12.

The various functions described below may be implemented or supported by artificial intelligence technology or one or more computer programs. Each of the programs consists of computer-readable program code and is implemented on a computer-readable medium. The terms "application" and "program" refer to one or more computer programs, software components, sets of instructions, procedures, functions, objects, classes, instances, associated data, and portions thereof suitable for implementing suitable computer-readable program code. The term "computer-readable program code" includes all types of computer code, including source code, object code, and executable code. The term "computer-readable medium" includes any type of media that may be accessed by a computer, such as a read-only memory (ROM), a random access memory (RAM), a hard disk drive, a compact disc (CD), a digital video disc (DVD), and any other type of memory. A "non-transitory" computer-readable medium excludes wired, wireless, optical, or other communications links that transmit transitory electrical or other signals. The non-transitory computer-readable media may include media on which data may be stored permanently, and media on which data may be stored and later overwritten, such as rewritable optical disks and erasable memory devices.

The various example embodiments of the present disclosure described below illustrate a hardware approach as an example. However, since various example embodiments of the present disclosure include techniques using both hardware and software, various example embodiments of the present disclosure do not exclude software-based approaches. Further, terms referring to control information, terms referring to entries, terms referring to network entities, terms referring to messages, terms referring to device components and the like used in the following description are examples for convenience of explanation. Therefore, the present disclosure is not limited to the terms described below, and other terms having an equivalent technical meaning may be used.

As illustrated in FIG. 1, the first wireless communication apparatus 11 may include an antenna 11_2, a transceiver 11_4, a processing circuitry 11_6, and a memory 11_8. In some example embodiments, the antenna 11_2, the transceiver 11_4, the processing circuitry 11_6 and the memory 11_8 may be included in a single package, or may be respectively included in different packages. The second wireless communication apparatus 12 may also include an antenna 12_2, a transceiver 12_4, a processing circuitry 12_6 and a memory 12_8. Hereinafter, duplicate descriptions of the first wireless communication apparatus 11 and the second wireless communication apparatus 12 will be omitted.

When a signal is transmitted, for example, in a transmission mode, the first wireless communication apparatus 11 may output a radio frequency (RF) signal, which is a signal converted from the processing circuitry 11_6 by the transceiver 11_4, to the outside by the antenna 11_2. When a signal is received, for example, in a reception mode, a signal received by the antenna 11_2 may be delivered to the transceiver 11_4. The antenna 11_2 may include a structure which may transmit and receive a high-speed pulse of a short time width to be suitable for UWB communication, and may have a radiation characteristic suitable for transmission or reception of a repetitive SHR signal.

The transceiver 11_4 may convert a digital signal provided from the processing circuitry 11_6 into an analog signal in a transmission mode, and may output a signal which has undergone analog processing such as modulation, amplification, filtering and the like through the antenna 11_2. The transceiver 11_4 may process a signal received through the antenna 11_2 in a reception mode by an analog circuitry such as a low-noise amplifier, a mixer, a filter, a power amplifier, an oscillator and the like before performing high-speed sampling to convert the same into a digital signal and provide the same to the processing circuitry 11_6. The transceiver 11_4 may generate and output a pulse signal which is repeatedly transmitted at a short time interval in a transmission mode, and may provide reference information for synchronization or channel estimation by detecting an SHR signal having a repeated structure in a reception mode. The transceiver 11_4 may switch between a transmission mode and a reception mode according to control of the processing circuitry 11_6, or may change a transceiving timing and a frequency setting.

The processing circuitry 11_6 may encode and modulate data inputted from a higher layer to generate a signal for transmission in a transmission mode, and may provide the generated signal to the transceiver 11_4. The processing circuitry 11_6 may extract data by demodulating and decoding a signal provided from the transceiver 11_4 in a reception mode, and may perform processing such as synchronization, channel estimation, signal detection and the like. The processing circuitry 11_6 may precisely estimate a transmission timing based on a repeated SHR signal structure in a reception mode, and may measure a channel impulse response (CIR) and a time difference of arrival (TDOA). The processing circuitry 11_6 may include programmable or reconfigurable hardware resources (a central processing unit (CPU), a digital signal processor (DSP), a field-programmable gate array (FPGA) and the like), or include an IP core performing a fixed function. The processing circuitry 11_6 may read or store data such as transmission data, reception data, a protocol parameter and a pulse sequence table by accessing an internal or external memory.

The memory 11_8 may be accessed by the processing circuitry 11_6, and may store data required for various operations. The memory 11_8 may store data to be transmitted in a transmission mode, an encoding parameter, a pulse pattern, SHR configuration information and the like, and may store a table for decoding in a transmission mode, reference information with respect to a repeated SHR sequence, a CIR estimation result, a synchronization reference value and the like. The memory 11_8 may include a volatile memory (for example, a dynamic random access memory (DRAM)) and/or a non-volatile memory (for example, a flash memory).

A series of operations performed by the transceiver 11_4 and/or the processing circuitry 11_6 may be referred to as an operation of the first wireless communication apparatus 11. An operation performed by an initiator or an access point (AP) may be performed by a transceiver and/or a processing circuitry included in a corresponding device, and an operation performed by a responder or a station (STA) may be performed by a transceiver and/or a processing circuitry included in a corresponding device.

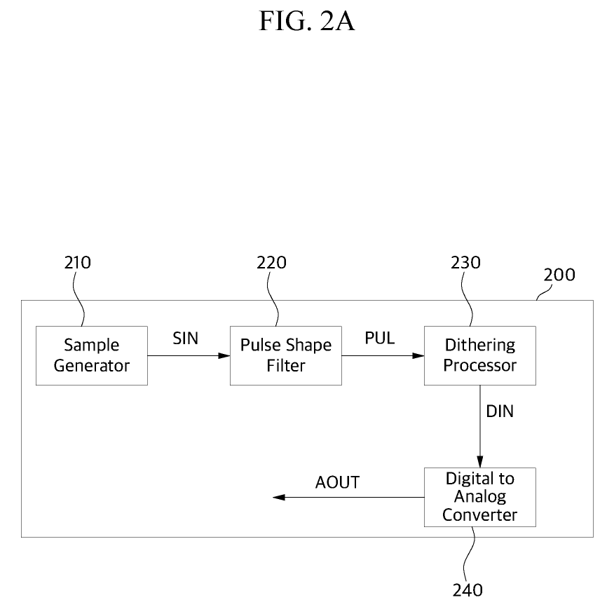

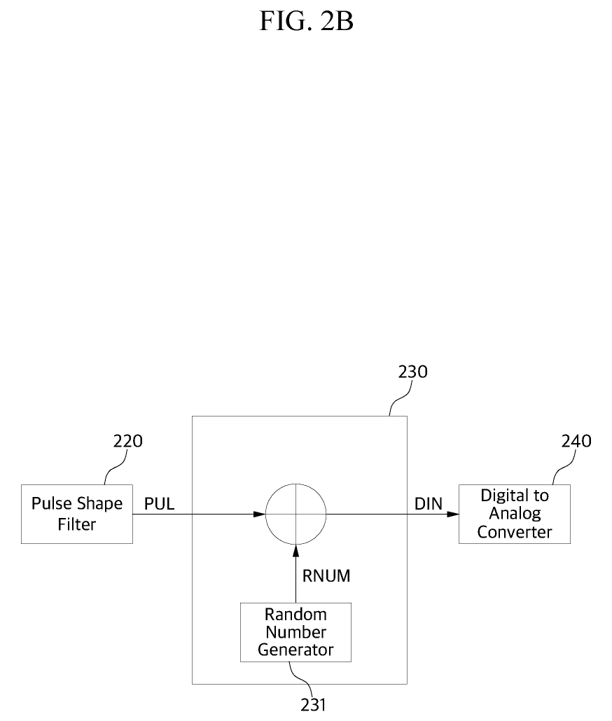

FIG. 2A is a block diagram illustrating processing circuitry of a wireless communication apparatus according to an example embodiment of the present disclosure. For example, processing circuitry 200 of FIG. 2A may be an example of the processing circuitry 11_6 and the processing circuitry 12_6 of FIG. 1.

Referring to FIG. 2A, the processing circuitry 200 according to an example embodiment may include a sample generator 210, a pulse shape filter 220, a dithering processor 230 and a digital to analog converter 240. The sample generator 210, the pulse shape filter 220, the dithering processor 230 and the digital to analog converter 240 may sequentially operate in order to generate an analog signal AOUT from an input sample.

In an example embodiment, the sample generator 210 may generate a sample according to a predefined pattern. The generated samples may correspond to a bit stream (e.g., baseband data or a particular symbol sequence). The sample generator 210 may generate a sample according to a predetermined regulation by internally referring to a random number generator, a code generator, or predefined table data, and the generated sample may be provided to the pulse shape filter 220 as an input sample.

In an example embodiment, samples generated by the sample generator 210 may be indicative of an SHR signal, and one sample may indicate one of +1, 0, and -1. For example, each sample that is generated by the sample generator 210 may be a digital number of +1, 0, or -1, and the samples may together form the SHR signal. Further, for an SHR signal, a predetermined combination may exist, and an index of a combination may be defined according to a length of code.

According to an example embodiment of the present disclosure, the pulse shape filter 220 may generate a pulse signal PUL by converting an input sample SIN provided from the sample generator 210 in a time domain and/or a frequency domain. For example, the pulse shape filter 220 may receive the plurality of samples from the sample generator 210, and may create a smooth pulse shape or waverform from the plurality of samples. The pulse shape filter 220 may be used for limiting a bandwidth of a transmission signal, controlling a spectrum (e.g., in which the pulse signal generated by the pulse shape filter 220 is within a specific frequency band), or suppressing an inter-symbol interference (ISI) in a communication system (e.g., to avoid interference between the pulse signal and other symbols), and may include a root raised cosine (RRC) filter and the like. A pulse signal generated by the pulse shape filter 220 may be delivered to the dithering processor 230.

Dithering may signify a technology of intentionally inserting fine noise to mitigate distortion caused by quantization and resolution limitation occurring in a digital signal. Noise insertion assists a continuous change of an original signal to be expressed in a more fractionized manner, may probabilistically disperse a quantization error in order for the same not to be focused on a particular section, thereby being able to implement a relatively natural signal even in a limited resolution environment. Further, dithering minimizes a gradation loss or expression distortion which may occur in a limited bit depth or sampling structure, thereby improving subjective perception and measuring quality.

A quantization error may signify an error caused by a difference generated between an input signal and a quantized signal because of the digital to analog converter 240 performing quantization for outputting a quantized value close to the input signal among quantized values. For example, the quantization error is the error between the input signal inputted to the digital to analog converter 240 and the outputted, quantized signal that is outputted from the digital to analog converter 240. When a signal generated from a signal quantized in the same manner as an SHR preamble signal is repeatedly transmitted in UWB communication, a quantization error may repeatedly occur.

According to an example embodiment, the dithering processor 230 may apply dithering to the pulse signal PUL provided from the pulse shape filter 220 to disperse quantization noise, thus reducing error caused during the digital to analog conversion. By decreasing a quantization error by dithering, a signal received at a receiving side may be easily processed, and communication quality may be improved. The dithering processor 230 may output a digital input signal DIN by receiving the pulse signal PUL, and the digital input signal DIN may be provided to the digital to analog converter 240. In embodiments, the digital input signal DIN may be generated by dithering the pulse signal PUL.

In an example embodiment, the dithering processor 230 may perform signal value-based dithering for mixing noise based on a pulse signal value with respect to the pulse signal PUL and/or time axis-based dithering for outputting a pulse signal value as a digital input signal at a point in time of sampling which is shaken by changing a point in time of sampling of a pulse signal. Accordingly, the dithering processor 230 may minimize or reduce an error caused by repeated transmission due to a quantization error.

In an example embodiment, the dithering processor 230 may, based on at least one of the point in time of sampling and the signal value of the pulse signal, generate a digital input signal. For instance, the dithering processor 230 may, based on a signal value and a plurality of quantization values of the digital to analog converter 240, determine a determination probability of the digital input signal at the point in time of sampling, and, based on the determination probability, determine the digital input signal.

In an example embodiment, the dithering processor 230 may generate the digital input signal by delaying or advancing the point in time of sampling of the pulse signal by a dithering time. For instance, if a reference point in time of sampling of the pulse signal is 10 nanoseconds (ns), the dithering processor 230 may set a range of ±1 ns for the dithering time, and accordingly, may adjust the point in time of sampling from 9 ns to 11 ns. Here, in a section in which an inclination of the pulse signal exists, a signal value obtained according to a change of the point in time of sampling may vary.

The dithering processor 230 may apply a displacement on a time axis in a random or pseudo-random manner, in order to generate a signal value which varies for each sampling with respect to an identical signal. Accordingly, the digital input signal inputted into the digital to analog converter 240 may have a temporally dispersed value, and may prevent a standardized quantization error which repeatedly occurs in an identical section during quantization. As a result, quantization error accumulation in an output of the digital to analog converter 240 may be reduced, and the quality of an output signal may be improved.

According to an example embodiment, the digital to analog converter 240 may convert the digital input signal DIN inputted from the dithering processor 230 into the analog signal AOUT. In a transmission path of a communication system, the converted analog signal AOUT may be used in an operation prior to being transmitted to an RF circuit or an antenna, and ultimately, may be outputted as a voltage- or current-based analog output signal.

According to an example embodiment, the digital to analog converter 240 may, when the dithering processor 230 changes a sampling time by time-axis dithering, perform quantization to correspond to the changed sampling time. For instance, when the sampling time of the dithering processor 230 is changed by -1 ns, a quantization time of the digital to analog converter 240 may also be changed by -1 ns, thereby performing quantization while factoring in the changed sampling time.

FIG. 2B is a block diagram illustrating a dithering processor according to an example embodiment of the present disclosure.

Referring to FIG. 2B, the dithering processor 230 may include a random number generator 231 according to an example embodiment. The random number generator 231 may, based on at least one of the point in time of sampling and the signal value of the pulse signal, calculate the determination probability of the digital input signal. The random number generator 231 may generate a random number signal RNUM according to the calculated determination probability. In embodiments, the random number signal may signify a signal representing a difference between the pulse signal PUL and a quantization value determined according to the determination probability.

In an example embodiment, the dithering processor 230 may identify a pulse signal value at a point in time of sampling of the pulse signal PUL outputted from the pulse shape filter 220. The random number generator 231 may generate the digital input signal DIN by generating the random number signal RNUM according to the pulse signal value and the quantization value before adding the random number signal RNUM to a signal value of the pulse signal PUL. The generated digital input signal DIN may be inputted into the digital to analog converter 240.

For instance, if the signal value at the point in time of sampling of the pulse signal PUL is 0.3 and the quantization value determined according to the determination probability is 0.4, the random number generator 231 may generate the random number signal RNUM of 0.1. Accordingly, 0.1 is the random number signal RNUM that is added to 0.3, which is the pulse signal PUL, thereby generating the digital input signal DIN.

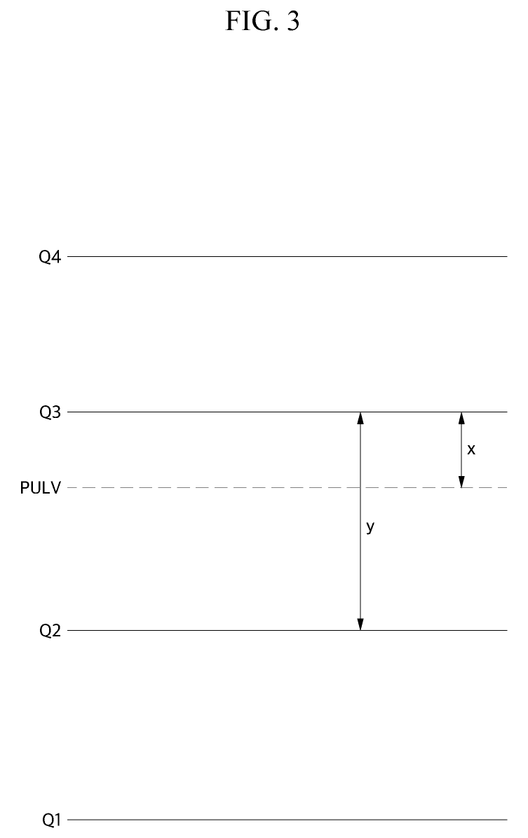

FIG. 3 illustrates a quantization value and a pulse signal value according to an example embodiment.

Referring to FIGS. 2A and 3, in an example embodiment, the dithering processor 230 may detect a first quantization value Q3 and a second quantization value Q2 which are the closest values to a pulse signal value PULV among a plurality of quantization values (e.g., the first quantization value Q3, the second quantization value Q2, a third quantization value Q1, and a fourth quantization value Q4). For example, the pulse signal value PULV is between the first quantization value Q3 and the second quantization value Q2, with zero other quantization values between the pulse signal value PULV and the first quantization value Q3, and zero other quantization values between the pulse signal value PULV and the second quantization value Q2, such that the two closest quantization values to the pulse signal value PULV are the first quantization value Q3 and the second quantization value Q2. Further, a value obtained by dividing a difference (x) between the pulse signal value PULV and the first quantization value Q3 by a difference (y) between the first quantization value Q3 and the second quantization value Q2 may be determined as the determination probability. Here, the first quantization value Q3 may be greater than the second quantization value Q2. In embodiments, the determination probability may be the difference between the pulse signal value PULV and a closest quantization value (e.g., the first quantization value Q3 in FIG. 3) divided by the difference between the two quantization values that the pulse signal value PULV is between (e.g., the first quantization value Q3 and the second quantization value Q2).

For example, a probability of a first quantization value being a digital input signal may be (1 – the determination probability). Further, a probability of a second quantization value being a digital input signal may be the determination probability.

For example, if the plurality of quantization values (e.g., the first quantization value Q3, the second quantization value Q2, the third quantization value Q1, and the fourth quantization value Q4) are respectively 0, 1, 2, and 3, and the pulse signal value PULV at a point in time of sampling of a pulse signal is 1.6, the dithering processor 230 may identify the value 2 as the first quantization value Q3 which is the closest to 1.6 while being 1.6 or greater, and identify the value 1 as the second quantization value Q2 which is the closest to 1.6 while being less than the first quantization value Q3 among the plurality of quantization values (e.g., the first quantization value Q3, the second quantization value Q2, the third quantization value Q1, and the fourth quantization value Q4). In this case, the dithering processor 230 may calculate 0.4, which is a value obtained by dividing 0.4, which is a difference (x) between 1.6, which is a pulse signal value PULV, and the first quantization value Q3 by 1, which is a difference between 2, which is the first quantization value Q3, and 1, which is the second quantization value Q2, as the determination probability. The dithering processor 230 may set 0.4, which is the determination probability, as a probability corresponding to the second quantization value Q2, and set 0.6 which is a remaining probability as a probability corresponding to the first quantization value Q3.

The dithering processor 230 may perform dithering in order for an average output during a predetermined period to converge to 1.6. For example, the original signal value (e.g., the pulse signal value PULV) is 1.6, and a method may comprise setting the digital input signal DIN as 1 (e.g., corresponding to Q2) with a probability of 0.4, and setting the digital input signal DIN as 2 (e.g., corresponding to Q3) with a probability of 0.6. Dithering may prevent repetitive error accumulation according to a fixed quantization boundary, and may maintain a statistical average of an output signal to be close to an original analog signal even without increasing the number of bits which is a digital resolution of the digital to analog converter 240. For example, if the pulse signal value PULV is 1.6 and the digital input signal DIN is repeatedly set to 2, then a repetitive error (e.g., of 0.4 each time the digital input signal DIN is set to 2) may accumulate over time. The dithering process 230 may therefore reduce the error over time.

In an example embodiment, the dithering processor 230 may acquire the number of transmissions of a transmission signal or the number of repetitions of a pattern, and, based on the number of repetitions of the pattern (or the number of transmissions of a transmission signal) and the determination probability, in a predetermined order, a digital input signal may be selected as the first quantization value Q3 or the second quantization value Q2.

For example, if the number of transmissions of the transmission signal is 100, the dithering processor 230 may, with respect to 1.6 which is an input signal value (PULV), transmit 1 (e.g., which is the second quantization value Q2) by 40 times, obtained by multiplying 0.4 which is the determination probability by 100 times, and transmit 2 (e.g., which is the first quantization value Q3) by 60 times, obtained by multiplying 0.6 which is the remaining probability by 100 times. As such, the number of transmissions and the determination probability may be used to select the quantization value for the digital input signal, thus reducing an accumulated error that may occur due to the input signal value (PULV) having a value that is slightly different than the two closest quantization values (Q2 and Q3). Further, the dithering processor 230 may determine in advance an order of outputting 2 which is the first quantization value Q3, and 1 which is the second quantization value Q2, as a digital input signal. For example, the first quantization value Q3 may be outputted first as a digital input signal 60 times, and the second quantization value Q2 may be outputted as a digital input signal for the remaining 40 times. An order in which the first quantization value Q3 and the second quantization value Q2 are outputted as a digital input signal may vary by setting. In embodiments, even when the outputted order between the two outputted quantization values (Q2 and Q3) differs, the second quantization value Q2 may nonetheless be outputted 40 times and the first quantization value Q3 may be outputted 60 times.

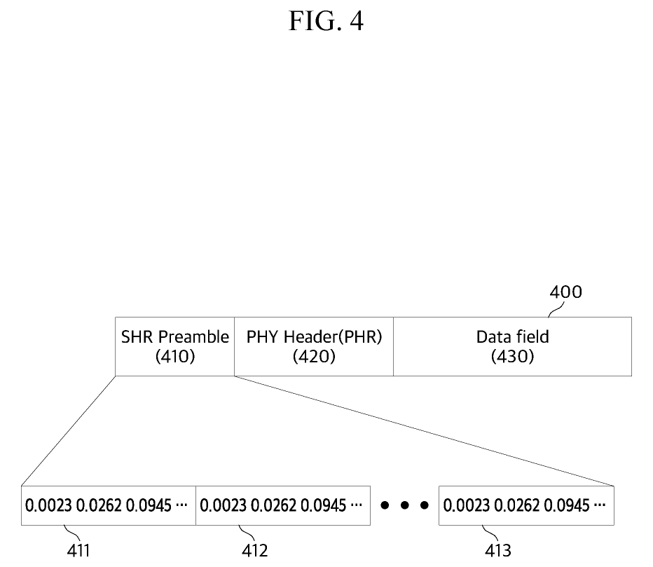

FIG. 4 is a structure chart illustrating transmission data according to an example embodiment of the present disclosure.

For example, FIG. 4 is a drawing illustrating a UWB physical layer (PHY) frame 400. According to an example embodiment of the present disclosure, the UWB PHY frame 400 may include an SHR preamble 410, a PHY header (PHR) 420, and a data field 430.

The SHR preamble 410 may be used for various algorithms performed in a receiving part such as automatic gain control (AGC), signal acquisition, frequency offset estimation, packet synchronization, channel estimation and ranging and the like. For example, the SHR preamble 410 may be utilized for processing such as AGC setting, antenna diversity selection, timing acquisition, frequency restoration, packet and frame synchronization, channel measurement, and leading edge signal tracking for ranging. The SHR preamble 410 may be arranged before the PHR 420, and may also be referred to as preamble code. In a wireless communication system, in order to synchronize a transmitting part and a receiving part, the SHR preamble 410 may be transmitted as a starting part of a frame (e.g., at the beginning of a frame prior to the PHR 420), and the SHR preamble 410 may have a fixed structure which is pre-arranged by a transmission device and a reception device. The reception device may recognize a starting point of the frame by the SHR preamble 410, and may be quickly synchronized with the transmitting part.

As illustrated in FIG. 4, according to repeated transmission of a transmission signal, the SHR preamble 410 may include a plurality of SHR signals, for example, a first SHR signal 411 and a second SHR signal 412 to an eighth SHR signal 413. Here, the first SHR signal 411 and the second SHR signal 412 to the eighth SHR signal 413 may all correspond to an identical signal having an identical pattern.

The PHR 420 may include information related to configuration of a physical layer protocol data unit (PPDU) and a protocol used to transmit the PPDU. For example, in a PHR, a physical layer parameter such as a length of a data field, transmission speed, a coding method and the like is included to facilitate the interpretation of data received afterwards from a receiving side.

The data field 430 may include user data which is transmitted and received, or a message of a higher layer. The corresponding data is encoded and modulated at a bit level to be transmitted by a PHY layer, and a receiving side may demodulate and decode the data in order to restore original data.

According to an example embodiment, the UWB PHY frame 400 may be configured to facilitate precise time synchronism between a transmitting part and a receiving part and support reliable data transmission, and the SHR preamble 410 included in a frame may be utilized as a core component for a high-precision ranging function which is characteristic of the UWB. Therefore, precise identification of the SHR preamble 410 by a reception device may be beneficial.

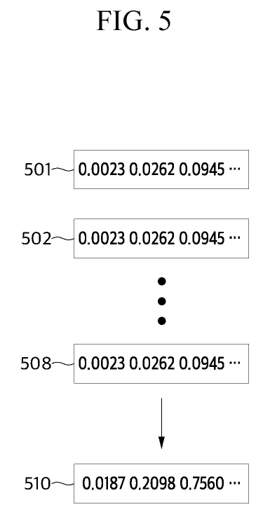

FIG. 5 illustrates reception data according to an example embodiment of the present disclosure.

Referring to FIGS. 1 and 5 , the processing circuitry 11_6 according to an example embodiment may receive an SHR preamble which has passed through a channel. The processing circuitry 11_6 may attempt synchronization by accumulating repeated patterns at an SHR preamble as described hereinafter.

In an example embodiment, in order to estimate a channel impulse response (CIR), the processing circuitry 11_6 may perform correlation calculation between a received baseband signal and a pre-defined signal pattern (for instance, a pseudo-noise (PN) code) transmitted within an SHR section. The processing circuitry 11_6 may improve an SNR by dividing the SHR section into predetermined length units and accumulating a correlation result value for each unit. For example, in a case of estimating a CIR only with a single symbol, distortion caused by multiple paths or a deteriorated wireless channel environment may be noticeable, the processing circuitry 11_6 may accumulate a correlation result with respect to the entire SHR length units to probabilistically disperse noise of a receiving side, thereby acquiring a precise channel response.

In an example embodiment, the processing circuitry 11_6 may perform a correlation calculation to detect a starting point of a signal from the received signal. A reception device may store a pre-defined sequence, which is repeatedly transmitted by a transmission device, as a reference sequence, and may multiply a predetermined section of the received signal by the reference sequence before accumulating a result of the multiplying, thereby calculating a correlation value.

The processing circuitry 11_6 may repeatedly calculate the correlation value in a method of having a plurality of time delays, in order to search for a time delay section in which the correlation value is maximized. The time delay section in which the correlation value is maximized may signify a point in time at which the received signal and the reference sequence are aligned, and the processing circuitry 11_6 may detect a starting position of a reception signal thereby.

In the correlation calculation, the processing circuitry 11_6 may divide a signal from noise by multiplying the signal including the noise by the reference sequence, and, by accumulation utilizing a repeated sequence, a signal component may be emphasized, and a noise component may be offset. For example, the transceiver 11_4 may acquire the correlation value by multiplying and adding the received signal and the reference sequence according to a time movement, wherein a point in time at which the correlation value is equal to or greater than a pre-defined threshold value may be set as a timing reference point of the signal. Accordingly, the processing circuitry 11_6 may detect a starting point of the pre-defined sequence in a reception signal by using a correlation multiplication calculation, and may perform synchronization at a precise timing of a transmission signal.

Noise which occurs during passage through a channel by repeatedly accumulating a received SHR signal may be probabilistically close to 0, but a quantization error which has occurred in a digital to analog converter of a transmission device may not be resolved. For instance, if a reception signal which is not based on noise which has occurred in a channel, is eight repeated signals of a first SHR signal 501 to an eighth SHR signal 508, when all of the signals are accumulated, a quantization error included in each signal may not be offset but, rather, may be accumulated by eight times to be calculated as an accumulated signal 510.

Because repeated patterns are accumulated, channel noise may decrease, but a quantization error may be accumulated and increase. As described above with reference to FIG. 2A, a quantization error may be minimized or reduced by using dithering.

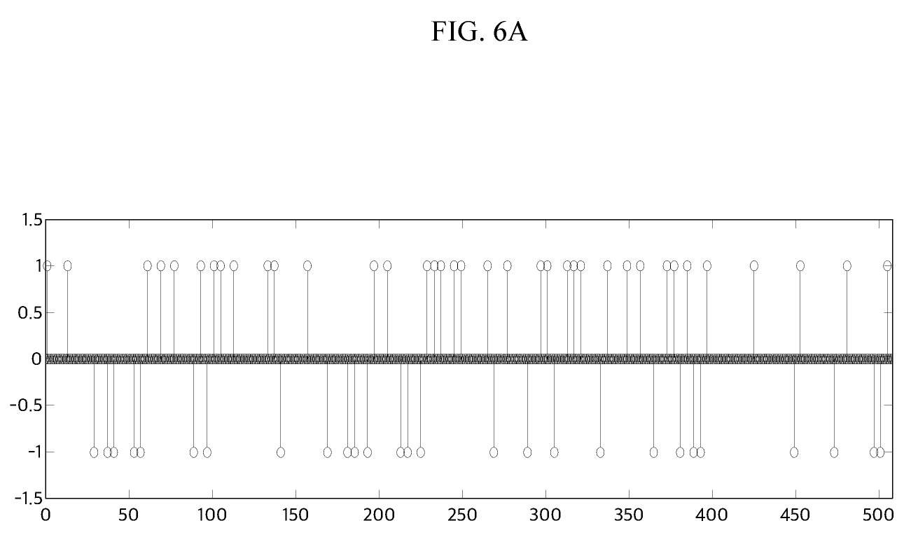

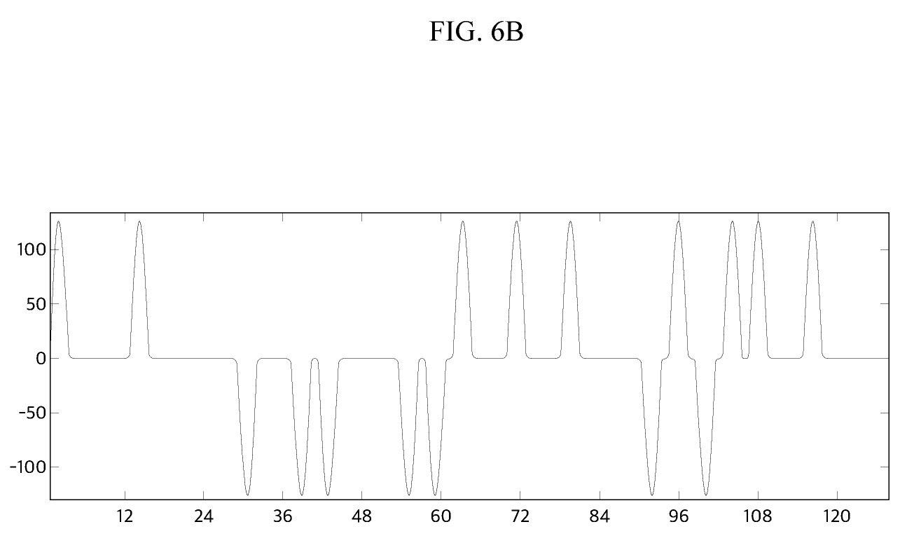

FIG. 6A is a graph illustrating one pattern repeated in a preamble according to an example embodiment of the present disclosure. One pattern which is a unit repeated in a preamble may be defined by code.

Referring to FIG. 6A, an x axis indicates a repeated pattern or code, and a y axis indicates a value of a repeated pattern or code. In an example embodiment, a value of a repeated pattern or code may be any one of 0, -1, and +1. Here, a code length may be defined as 31, 91, and 127. For instance, when a code length is 127, a first signal of a code index may be pre-defined as (+1, 0, 0, +1, 0, 0, 0, -1, 0, -1, -1, 0, 0, -1, -1, +1, 0, +1, 0, +1, 0, 0, -1, +1, -1, +1, +1, 0, +1, 0, 0, 0, 0, +1, +1, -1, 0, 0, 0, +1, 0, 0, -1, 0, 0, -1, -1, 0, -1, +1, 0, +1, 0, -1, -1, 0, -1, +1, +1, +1, 0, +1, +1, 0, 0, 0, +1, -1, 0, +1, 0, 0, -1, 0, +1, +1, -1, 0, +1, +1, +1, 0, 0, -1, +1, 0, 0, +1, 0, +1, 0, -1, 0, +1, +1, -1, +1, -1, -1, +1, 0, 0, 0, 0, 0, 0, +1, 0, 0, 0, 0, 0, -1, +1, 0, 0, 0, 0, -1, 0, 1, 0, 0, 0, -1, -1, +1).

For an SHR symbol, included in an SHR signal after three 0s are additionally inserted between code values, 0 to 508 indices may exist. For instance, if a signal is (+1, 0, -1), three 0s may be added after the signal as (+1, 0, 0, 0, 0, 0, 0, 0, -1, 0, 0, 0). Because 0 is inserted between signals, a time interval between adjacent pulses may be guaranteed, which may prevent inter-pulse interference. Further, because each symbol is converted into a sample sequence of a fixed length, a signal processing procedure such as correlation calculation, filtering, or time synchronization in a digital domain may be simplified and standardized. Further, a reception device performs a correlation processing by a sample unit based on a time-extended SHR sequence, thereby improving precision in synchronization and accuracy in channel response estimation.

FIG. 6B is a graph illustrating a pulse signal according to an example embodiment of the present disclosure.

Referring to FIG. 6B, identified is a signal which is obtained after symbols corresponding to 0 to 124 of the SHR signal of FIG. 6A has passed through a Kaiser filter of which a beta parameter is 8. The Kaiser filter is a filter for forming a waveform of a transmission or reception signal, and a Kaiser window-based pulse shape filter may be applied. A Kaiser window is one of window functions which are generally used for designing a digital filter, and provides a parameter for adjusting a balance between a size of a side lobe and a width of a main lobe in a frequency area. Accordingly, the Kaiser filter may be designed to correspond to a desired bandwidth and a passage characteristic, and may be implemented in a finite impulse response (FIR) filter structure.

The window function at the Kaiser filter may include a beta parameter of a real value for determining a shape of a window. In some embodiments, there may be a tendency that, the smaller a beta parameter value is, the narrower a main lobe becomes but the greater a side lobe becomes, and the greater a beta parameter value is, the smaller a size of a side lobe may become, but the greater a width of a main lobe may become. Therefore, a parameter value may function as an element for determining a tradeoff between a waveform duration time in a time area and a band limitation characteristic in a frequency area. For instance, in case that a beta parameter value is set at 8, a filter characteristic for guaranteeing a temporal resolution of a predetermined level while maintaining high frequency selectivity and a small side lobe may be provided.

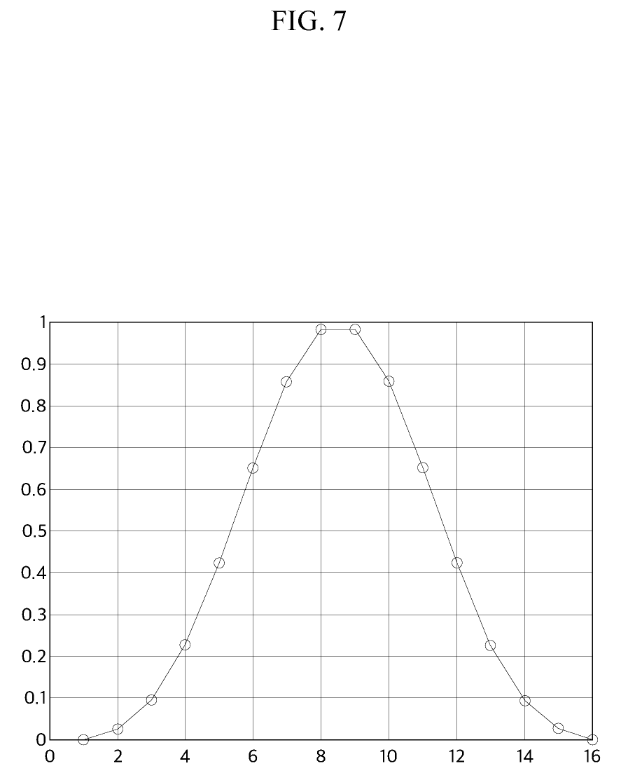

FIG. 7 is a graph illustrating a normalized pulse signal according to an example embodiment of the present disclosure. In FIG. 7, an x axis indicates an index of a point in time of sampling, and a y axis indicates a value of a normalized pulse signal.

Referring to FIGS. 1 and 7, a pulse signal may be normalized to identify a pulse signal value at 16 points in time of sampling. Normalization may signify a process of adjusting a range of a digital sample to correspond to a predetermined standard based on a maximum amplitude or an average power of a pulse signal. The processing circuitry 12_6 may satisfy a transmission power limit applied to a UWB communication system by a normalization process. For instance, in order for a spectrum of a transmission signal not to exceed a power spectral density (PSD) limit of a regulating organization, the processing circuitry 12_6 may control power of a digital signal in advance by normalization. Further, by normalizing a digital signal at an amplitude suitable for an input range of digital to analog conversion, the processing circuitry 12_6 may cause the digital to analog converter 240 of FIG. 2A to output an analog signal without distortion.

In an example embodiment, the processing circuitry 12_6 may detect a synchronization point by performing correlation calculation with respect to a received SHR signal. Here, with a transmission device transmitting a normalized SHR signal, the processing circuitry 12_6 may maintain a size of a correlation value at a predetermined standard, and may detect a point of synchronization in a more precise manner in a predetermined threshold value standard.

For instance, at the 16 points in time of sampling, a value of a pulse signal may individually be: 0.0023, 0.0262, 0.0945, 0.2268, 0.4229, 0.6525, 0.8598, 0.9835, 0.9835, 0.8598, 0.6525, 0.4229, 0.2268, 0.0945, 0.0262, 0.0023. Depending on a sign of an SHR symbol, a value of a pulse signal generated at the 16 points in time of sampling may be multiplied by +1 or -1 to generate a final pulse signal, and the generated pulse signal may be inputted into the digital to analog converter 240 of FIG. 2A.

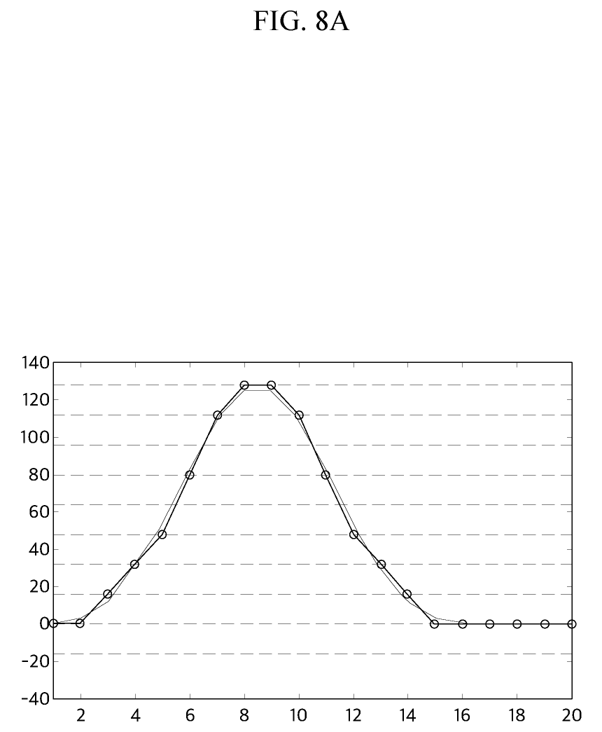

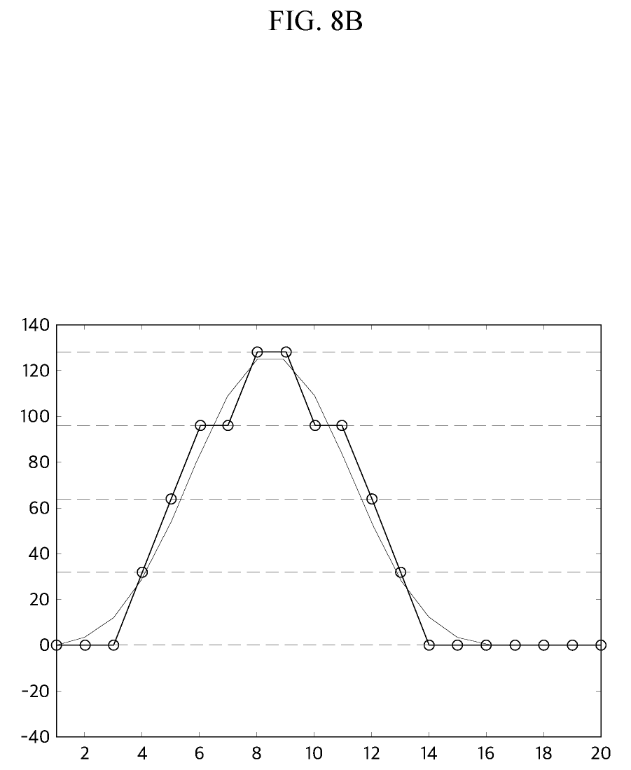

FIG. 8A is a graph illustrating a quantization result of digital to analog conversion according to an example embodiment of the present disclosure, and FIG. 8B is a graph illustrating a quantization result of digital to analog conversion according to an example embodiment of the present disclosure. In a graph, an x axis indicates an index of sampling time, and a y axis indicates a pulse signal value or a quantization value.

Referring to FIGS. 2A, 8A and 8B, before the digital to analog converter 240 converts a pulse signal from a digital signal into an analog signal, the corresponding digital signal may be quantized at the pre-defined number of bits. Quantization may affect precision of a signal and a calculation load of a transceiving device, and accordingly, the various numbers of bits may be applied.

The graph illustrated in FIG. 8A indicates a pulse signal quantized by using 4 bits including a sign bit, and may indicate a signal having a discrete value of 16 stages in total (from -8 to +7). The corresponding graph may show a shape which maintains a curved line similar to a shape of an original analog signal while including a quantization staircase. Quantization with 4 bits including a sign bit may guarantee a predetermined level of precision while efficiently limiting an amount of calculation.

The graph illustrated in FIG. 8B indicates a pulse signal quantized by using 3 bits including a sign bit, and may indicate a signal having a discrete value of 8 stages in total (from -4 to +3). The corresponding graph more clearly indicates a stair structure compared to quantization with 4 bits including a sign bit, and may indicate a greater discontinuous aspect deviating from an original continuous signal curved line. As the number of quantization bits decreases, signal distortion increases, and a relatively great quantization noise may occur.

Therefore, the processing circuitry 12_6 may select the number of quantization bits according to a quality requirement level of a signal, power consumption of a system, complexity of calculation or the like, and 4 bits including a sign bit may provide a higher expression precision and a low quantization error compared to 3 bits including a sign bit. In case that the number of quantization bits increases, complexity of the digital to analog converter 240 of FIG. 2A may increase, and power consumption may increase, and latency may increase. In particular, in a case of the processing circuitry 12_6 which operates in an ultra-low power environment, using the high number of bits may hinder power efficiency of an entire system.

According to an example embodiment of the present disclosure, the processing circuitry 12_6 may effectively reduce a quantization error occurring at the digital to analog converter 240 of FIG. 2A by applying dithering without increasing the number of quantization bits. For instance, the processing circuitry 12_6 may prevent an error component generated upon quantization from being periodically accumulated by adding a dithering signal to a digital signal, and may mitigate distortion of an output waveform by such processing. Therefore, the processing circuitry 12_6 may generate a high-quality analog output signal while maintaining the relatively low number of bits.

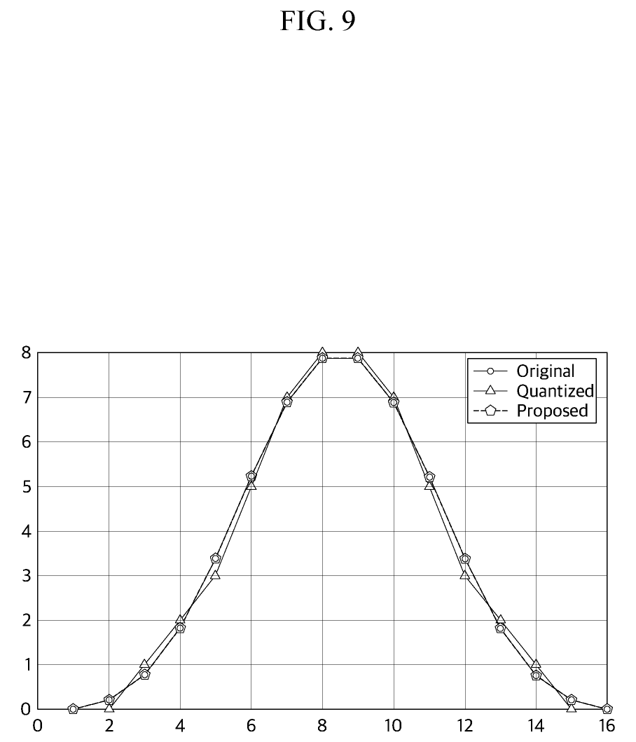

FIG. 9 is a graph illustrating a quantization error in a wireless communication apparatus according to an example embodiment of the present disclosure. In the graph, an x axis indicates an index of sampling time for quantization, and a y axis indicates a pulse signal value or a quantization value.

Referring to FIGS. 2 and 9 , the graphs respectively indicate an original pulse signal marked as "Original," a quantized pulse signal marked as "Quantized," and a signal to which the dithering processor 230 is applied which is marked as "Proposed", and may correspond to a result after the processing circuitry 12_6 accumulates a received signal by 100 times.

When the dithering processor 230 is omitted, without being based on noise caused by a channel or a temperature, a quantization error to an original pulse signal at each point in time of sampling may be shown as (0.0187, 0.2098, -0.2440, -0.1858, 0.3828, 0.2198, -0.1216, -0.1320, -0.1320, -0.1216, 0.2198, 0.3828, -0.1858, -0.2440, 0.2098, 0.0187). In this case, an error rate of 0.1893 on average may be provided. For example, the quantization error may reflect the difference between the value of the original pulse signal (e.g., “Original”) and the value of the quantized pulse signal (e.g., “Quantized”) at a point in time. For example, at time point 5, the difference between the value of the original pulse signal (e.g., “Original”) and the value of the quantized pulse signal (e.g., “Quantized”) is 0.3828, and at time point 6, the difference between the value of the original pulse signal (e.g., “Original”) and the value of the quantized pulse signal (e.g., “Quantized”) is 0.2198. Accordingly, without the dithering processor 230, the quantization error may accumulate over time.

When the dithering processor 230 is applied to an example embodiment, without being based on noise caused by a channel or a temperature, a quantization error to an original pulse signal at each point in time of sampling may be shown as (-0.0013, -0.0002, -0.0040, 0.0042, 0.0028, -0.0002, -0.0016, -0.0020, -0.0020, -0.0016, -0.00027, 0.0028, 0.0042, -0.0040, -0.0002, -0.0013). In this case, an error rate of 0.002 on average may occur, and thus, a case of having undergone a dithering process by the dithering processor 230 according to an example embodiment may facilitate a decrease in an error rate by 98.94% compared to a case in which the dithering processor 230 does not exist. For example, at time point 5, the quantization error is the difference between the value of the original pulse signal (e.g., “Original”) and the value of the proposed pulse signal (e.g., “Proposed”) is 0.0028, and at time point 6, the difference between the value of the original pulse signal (e.g., “Original”) and the value of the proposed pulse signal (e.g., “Proposed”) is -0.0002. Accordingly, by providing the dithering processor 230, the quantization error may be reduced.

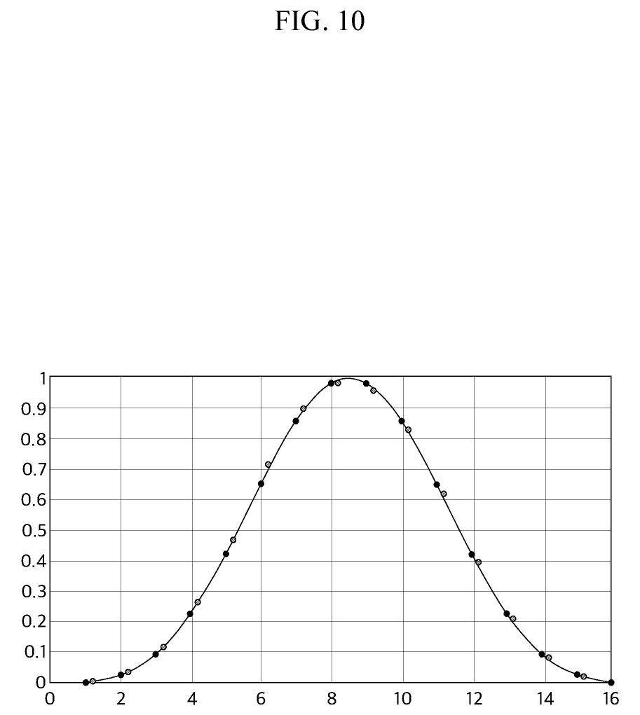

FIG. 10 is a graph illustrating a dithering result according to an example embodiment of the present disclosure. In the graph, an x axis indicates sampling time, and a y axis indicates a sampled quantization value.

Referring to FIG. 10, a black dot may correspond to 16 signal values which are sampled from 1 to 16 which are reference sampling times, and a white dot may correspond to a signal value sampled by delaying the reference sampling times by +0.2. The present disclosure is not limited to a delay of +0.2, and other times may be selected. In addition, the reference sampling times may be delayed (e.g., by a number greater than zero) or advanced (e.g., by a number less than zero), thus allowing for delaying or advancing of the point in time of sampling of the pulse signal by a dithering time, which may reduce the accumulated quantization error as described herein. Further, a dithering time may be applied differently between one digital input signal and another digital input signal, for example, with a first dithering time being applied to a first digital input signal, and a second dithering time being applied to a second digital input signal, with the first dithering time being different from the second dithering time. In the reference sampling time, pulse signal values (e.g., represented by the black dot in FIG. 10) may be (0.0023, 0.0262, 0.0945, 0.2268, 0.4229, 0.6525, 0.8598, 0.9835, 0.9835, 0.8598, 0.6525, 0.4229, 0.2268, 0.0945, 0.0262, 0.0023). Further, pulse signal values according to a sampling time delayed by 0.2 (e.g., represented by the white dot in FIG. 10) may be shown as (0.0071, 0.0399, 0.121, 0.266, 0.4688, 0.7159, 0.9024, 0.9835, 0.9587, 0.8327, 0.6203, 0.3962, 0.2122, 0.0836, 0.0213, 0.0055).

In this case, if quantization values are evenly divided into 8 from 0 to 1 by the digital to analog converter 240 of FIG. 2A, a seventh signal value of a reference sampling time may be 0.8598, and a seventh signal value of a delayed sampling time may be 0.9024. The seventh signal value of the reference sampling time may be set at a quantization value of 0.8571 by quantization, and the seventh signal value of the delayed sampling time may be set at a quantization value of 1 by quantization, so as not to have an identical quantization value.

Similarly, an eleventh signal value of a reference sampling time may be 0.6525, and an eleventh signal value of a delayed sampling time may be 0.6203. The eleventh signal value of the reference sampling time may be set as a quantization value of 0.7143 by quantization, and the eleventh signal value of the delayed sampling time may be set as a quantization value of 0.5714 by quantization, so as not to have an identical quantization value.

Because the dithering processor 230 of FIG. 2A dithers signal values of a pulse signal by varying a sampling time in a time axis, the signal values may have various quantization values, and accordingly, a quantization error may be reduced. For example, by delaying the reference sampling time with the dithering processor 230, the quantization error may be reduced. In particular, as illustrated in FIG. 10, the black dots represent the pulse signal values, and pulse signal values may be the same: for example, with the pulse signal values at the first and sixteenth sampling times being the same (e.g., 0.0023), the pulse signal values at the second and fifteenth sampling times being the same (e.g., 0.0262), the pulse signal values at the third and fourteenth sampling times being the same (e.g., 0.0945), etc. As such, without the dithering processor 230 applying a delay to the reference sampling times, the quantization error may accumulate: for example, with the quantization error at the first and sixteenth sampling times being the same, the quantization error at the second and fifteenth sampling times being the same, the quantization error at the third and fourteenth sampling times being the same, etc. However, due to the dithering processor 230 applying the delay, the quantization errors may not be the same, which may result in a reduction of the quantization error over time. For example, the pulse signal values at the first and sixteenth sampling times (e.g., when delayed by +0.2) are not the same (e.g., 0.0071 and 0.0055), the pulse signal values at the second and fifteenth sampling times (e.g., when delayed by +0.2) are not the same (e.g., 0.0399 and 0.0213), the pulse signal values at the third and fourteenth sampling times (e.g., when delayed by +0.2) are not the same (e.g., 0.121 and 0.0836), etc. Accordingly, due to the delay, the quantization error at the first sampling time may be different than the quantization error at the sixteenth sampling time, the quantization error at the second sampling time may be different than the quantization error at the fifteenth sampling time, the quantization error at the third sampling time may be different than the quantization error at the fourteenth sampling time, etc.

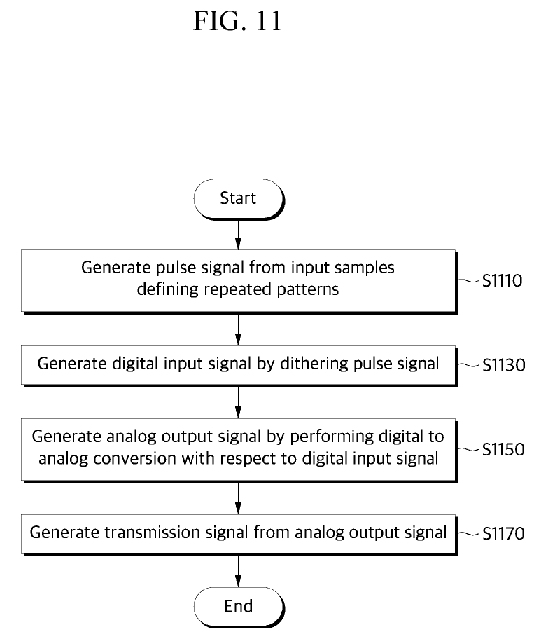

FIG. 11 illustrates a flowchart of a method for reducing a quantization error according to an example embodiment of the present disclosure.

Referring to FIGS. 1 and 11 , in operation S1110, the first wireless communication apparatus 11 may generate a pulse signal from input samples defining repeated patterns according to an example embodiment. Here, the repeated patterns may be set in advance in a shape of code, and a value of each code may have one of 0, -1, and +1. Further, the repeated patterns may be generated with a predetermined number of 0s being added to the pre-set code. For instance, if a signal is (+1, 0, -1), three 0s may be added after the signal as in (+1, 0, 0, 0, 0, 0, 0, 0, -1, 0, 0, 0). Because 0 is inserted between signals, a time interval between adjacent pulses may be guaranteed, in order to prevent inter-pulse interference.

In operation S1130, the first wireless communication apparatus 11 according to an example embodiment may generate a digital input signal by dithering the pulse signal. For instance, in case that a sample value of the pulse signal PUL is positioned at a boundary of a particular quantization section, the first wireless communication apparatus 11 may probabilistically determine a value of the corresponding signal as one of upper and lower adjacent quantization values (e.g., as illustrated and described relative to FIG. 3). Alternatively, the first wireless communication apparatus 11 may change a point in time of sampling within a predetermined range from a reference point in time in order to extract sample values different from each other in an inclination section of the pulse signal (e.g., as illustrated and described relative to FIGS. 9-10). A statistical distribution of the digital input signal may be maintained to be similar to an original analog signal, while mitigating quantization error accumulation.

In operation S1150, the first wireless communication apparatus 11 may generate an analog output signal by performing digital to analog conversion with respect to the digital input signal according to an example embodiment. The first wireless communication apparatus 11 may convert the digital input signal generated in operation S1130 into the analog output signal by the digital to analog converter 240 of FIG. 2A. The wireless communication apparatus 11 generates a corresponding voltage or current signal with reference to an inputted digital value, wherein the generated analog signal may be provided in a continuous waveform which may be used in a wireless transmission-only circuitry.

For instance, if a digital input value is 5, the wireless communication apparatus 11 may output an analog voltage of 0.5 volts (V) corresponding to a corresponding digital input value, and an output waveform of a pulse shape may be formed according to a sequence of continuous input values. A digital input value to which dithering is applied generates an analog output similar to an original pulse signal on average, and thus, a signal quality may be improved compared to a case in which dithering is not performed.

In operation S1170, the first wireless communication apparatus 11 according to an example embodiment may generate a transmission signal from the analog output signal. The first wireless communication apparatus 11 may modulate and amplify the analog output signal outputted in operation S1150 into the transmission signal suitable for wireless transmission to deliver the same to a transmission path. The generated transmission signal is transmitted by being dispersed in an ultra-wideband frequency band according to a UWB, and may be restored by correlation detection and the like in the second wireless communication apparatus 12 which is a receiving side apparatus.

For instance, the first wireless communication apparatus 11 may apply frequency modulation or time diffusion code to the analog output signal to form the final transmission signal, and afterwards, may amplify the same to a desired output power level by an RF power amplifier before dispersing the same by an antenna. The transmission signal satisfies a waveform characteristic within a predetermined UWB band, and, because a quantization error is reduced due to dithering-based processing, precision in synchronization at a receiving side and demodulation performance may be improved.

The second wireless communication apparatus 12 according to an example embodiment may accumulate a repeated SHR preamble signal received from the first wireless communication apparatus 11 to disperse quantization noise or channel noise to estimate a CIR.

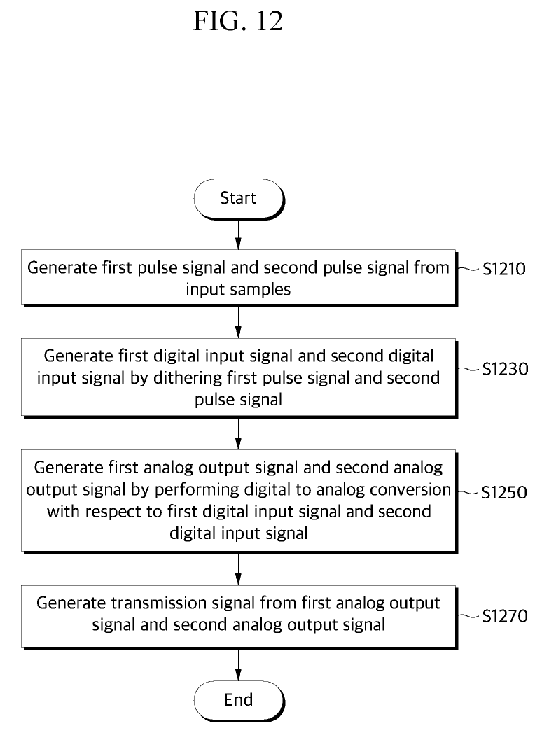

FIG. 12 illustrates a flowchart of a method for reducing a quantization error according to an example embodiment of the present disclosure.

Referring to FIG. 12, in operation S1210, the first wireless communication apparatus 11 according to an example embodiment may generate a first pulse signal and a second pulse signal from input samples. For instance, the first wireless communication apparatus 11 may generate the first pulse signal and the second pulse signal based on a reference input sequence which is identical input samples. Here, the input samples may be set in advance in a shape of code, and a value of each code may have one of 0, -1, and +1. Further, repeated patterns may be generated with a predetermined number of 0s being added to the pre-set code.

In operation S1230, the first wireless communication apparatus 11 according to an example embodiment may generate a first digital input signal and a second digital input signal by dithering the first pulse signal and the second pulse signal. The first wireless communication apparatus 11 may, with respect to each of the first pulse signal and the second pulse signal, apply dithering by performing at least one of time axis-based dithering and signal value-based dithering.

In an example embodiment, time axis-based dithering may signify a method of obtaining different signal values at an inclination section of a pulse signal by arbitrarily adjusting a point in time of sampling within a predetermined time range around a reference point in time of sampling. Signal value-based dithering may be performed in a method of adding or subtracting a small noise component to or from a sampled signal value, which may be utilized for determining to which side a value close to a quantization boundary is to be classified between upper/lower adjacent quantization values.

According to an example embodiment, the first wireless communication apparatus 11 may generate the first pulse signal and the second pulse signal according to a determination probability by calculating the determination probability at which an adjacent quantization value close to a quantization boundary at which a signal value is positioned is to be generated. Further, the first wireless communication apparatus 11 may generate the first pulse signal and the second pulse signal as a quantization value in a predetermined order according to the number of repetitions and the determination probability. The first wireless communication apparatus 11 may contribute to dispersing quantization error accumulation which may occur during repeated transmission of a digital input signal generated by dithering.

Because the first wireless communication apparatus 11 performs dithering, the second digital input signal may be different from the first digital input signal. For example, because the first wireless communication apparatus 11 dithers the first pulse signal and the second pulse signal which correspond to identical patterns, the first digital input signal and the second digital input signal which are different from each other may be generated.

In operation S1250, the first wireless communication apparatus 11 may perform digital to analog conversion with respect to the first digital input signal and the second digital input signal to generate a first analog output signal and a second analog output signal according to an example embodiment. For instance, the first wireless communication apparatus 11 may convert the first and second digital input signals, which are dithered by the digital to analog conversion, into an analog waveform respectively. In a case in which time axis-based dithering is applied, an analog output signal may be formed in a waveform of which a pulse location is finely and temporally modulated, and, in a case in which signal value-based dithering is applied, the same may be outputted in an analog waveform in which an amplitude or an area of each pulse is statistically dispersed.

In operation S1270, the first wireless communication apparatus 11 may generate a transmission signal from the first analog output signal and the second analog output signal according to an example embodiment. The first wireless communication apparatus 11 may modulate and amplify the analog output signal outputted in operation S1250 into the transmission signal suitable for wireless transmission to deliver the same to a transmission path. The generated transmission signal is transmitted by being dispersed in an ultra-wideband frequency band according to a UWB method, and may be restored by correlation detection and the like in the second wireless communication apparatus 12 which is a receiving side apparatus.

For instance, the first wireless communication apparatus 11 may apply frequency modulation or time diffusion code to the analog output signal to form the final transmission signal, and afterwards, may amplify the same to a desired output power level by an RF power amplifier before dispersing the same by an antenna. The transmission signal satisfies a waveform characteristic within a predetermined UWB band, and, because a quantization error is reduced due to dithering-based processing, precision in synchronization at a receiving side and demodulation performance may be improved.

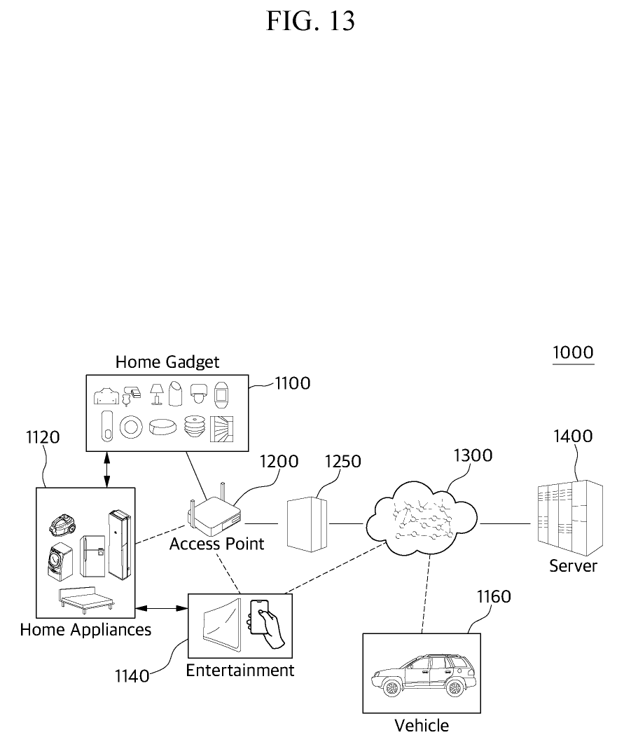

FIG. 13 is a drawing illustrating examples of a device for wireless communication according to an example embodiment of the present disclosure.

Referring to FIG. 13, an Internet of things (IoT) network system 1000 may include a plurality of IoT devices (e.g., a home gadget group 1100, a home appliances/furniture group 1120, an entertainment group 1140, and a transportation means group 1160), an access point 1200, a gateway 1250, a wireless network 1300, and a server 1400. The IoT may signify a network between objects using wired/wireless communication.

Each of the IoT devices (e.g., the home gadget group 1100, the home appliances/furniture group 1120, the entertainment group 1140, and the transportation means group 1160) may form a group according to a characteristic of each IoT device. For instance, the IoT devices may be grouped in the home gadget group 1100, the home appliances/furniture group 1120, the entertainment group 1140, the transportation means group (vehicle) 1160 or the like. The plurality of IoT devices (e.g., the home gadget group 1100, the home appliances/furniture group 1120, and the entertainment group 1140) may be connected to a communication network or connected to another IoT device by the access point 1200. The access point 1200 may be built in one IoT device. The gateway 1250 may change a protocol in order for the access point 1200 to access an external wireless network. The IoT devices (e.g., the home gadget group 1100, the home appliances/furniture group 1120, and the entertainment group 1140) may be connected to an external communication network by the gateway 1250. The wireless network 1300 may include the Internet and/or a public network. The plurality of IoT devices (e.g., the home gadget group 1100, the home appliances/furniture group 1120, the entertainment group 1140, and the transportation means group 1160) may be connected to the server 1400 providing a predetermined service by the wireless network 1300, and a user may use the service through at least one of the plurality of IoT devices (e.g., the home gadget group 1100, the home appliances/furniture group 1120, the entertainment group 1140, and the transportation means group 1160).

As described above, example embodiments have been disclosed in the drawings and the specification. Although the example embodiments have been described using specific terminology in this specification, the same is used only for the purpose of describing the technical spirit of the present disclosure and is not used to limit the scope of the present disclosure as defined in the claims. Therefore, those of ordinary skill in the art will understand that various modifications and other equivalent example embodiments are possible therefrom.

What is claimed is:

1. A method of generating a transmission signal for wireless communication, comprising:
generating a pulse signal from input samples defining repeated patterns;
generating a digital input signal by dithering the pulse signal;
generating an analog output signal by performing digital to analog conversion with respect to the digital input signal; and
generating the transmission signal from the analog output signal.

2. The method of claim 1, wherein the generating of the digital input signal is performed based on at least one of a point in time of sampling and a signal value of the pulse signal.

3. The method of claim 2, wherein the generating of the digital input signal comprises:
determining, based on a plurality of quantization values of the digital to analog conversion and the signal value, a determination probability of the digital input signal at the point in time of sampling; and
determining, based on the determination probability, the digital input signal.

4. The method of claim 3, wherein the determining of the determination probability comprises:
detecting a first quantization value and a second quantization value which are the closest quantization values to the signal value among the plurality of quantization values, wherein the signal value is between the first quantization value and a second quantization value; and
determining a determination probability by dividing a difference between the signal value and the first quantization value by a difference between the first quantization value and the second quantization value,
wherein the first quantization value is greater than the second quantization value.

5. The method of claim 4, wherein a probability of the first quantization value being the digital input signal is (1 – the determination probability), and
wherein a probability of the second quantization value being the digital input signal is the determination probability.

6. The method of claim 4, further comprising acquiring a number of repetitions of the repeated patterns,
wherein the digital input signal is selected as the first quantization value or the second quantization value in a predetermined order based on the number of repetitions and the determination probability.

7. The method of claim 2, wherein the generating of the digital input signal comprises generating the digital input signal by delaying or advancing the point in time of sampling of the pulse signal by a dithering time.

8. The method of claim 1, wherein the transmission signal is transmitted in an ultra wideband (UWB).

9. The method of claim 8, wherein the repeated patterns are included in a synchronization header (SHR) preamble.

10. A method of generating a transmission signal for wireless communication, comprising:
generating a first pulse signal and a second pulse signal respectively to correspond to identical patterns from input samples;
generating a first digital input signal and a second digital input signal respectively by dithering the first pulse signal and the second pulse signal;
generating a first analog output signal and a second analog output signal respectively by performing digital to analog conversion with respect to the first digital input signal and the second digital input signal; and
generating the transmission signal from the first analog output signal and the second analog output signal,
wherein the second digital input signal is different from the first digital input signal.

11. The method of claim 10, wherein the generating of the first digital input signal and the second digital input signal respectively is performed based on at least one of a point in time of sampling and a signal value of the first pulse signal or the second pulse signal.

12. The method of claim 11, wherein the generating of the first digital input signal comprises generating the first digital input signal by delaying or advancing a point in time of sampling of the first pulse signal by a first dithering time, and the generating of the second digital input signal comprises generating the second digital input signal by delaying or advancing a point in time of sampling of the second pulse signal by a second dithering time, wherein the first dithering time is different from the second dithering time.

13. A device for generating a transmission signal for wireless communication comprising:
a pulse shape filter configured to generate a pulse signal from input samples defining repeated patterns;
a dithering processor configured to generate a digital input signal by dithering the pulse signal;
a digital to analog converter configured to generate an analog output signal from the digital input signal; and
a transceiver configured to generate the transmission signal from the analog output signal.

14. The device of claim 13, wherein the dithering processor is configured to generate the digital input signal based on at least one of a point in time of sampling and a signal value of the pulse signal.

15. The device of claim 14, wherein the dithering processor is configured to:
determine, based on a plurality of quantization values of the digital to analog converter and the signal value, a determination probability of the digital input signal at the point in time of sampling; and
determine, based on the determination probability, the digital input signal.

16. The device of claim 15, wherein the dithering processor is configured to:
detect a first quantization value and a second quantization value which are the closest quantization values to the signal value among the plurality of quantization values, wherein the signal value is between the first quantization value and the second quantization value; and
determine a determination probability by dividing a difference between the signal value and the first quantization value by a difference between the first quantization value and the second quantization value.

17. The device of claim 16, wherein a probability of the first quantization value being the digital input signal is (1 – the determination probability), and
wherein a probability of the second quantization value being the digital input signal is the determination probability.

18. The device of claim 16, wherein the dithering processor is configured to obtain a number of repetitions of the repeated patterns, and
wherein the digital input signal is selected as the first quantization value or the second quantization value in a predetermined order based on the number of repetitions and the determination probability.

19. The device of claim 14, wherein the dithering processor is configured to generate the digital input signal by delaying or advancing the point in time of sampling of the pulse signal by a dithering time.

20. The device of claim 13, wherein the transmission signal is transmitted in a UWB.
